(19) United States
(12) Patent Application Publication
(10) Pub. No.: US 2024/0085310 A1
(43) Pub. Date: Mar. 14, 2024

(54) Resistance-Based Sensor System for Measuring Atmospheric Corrosion

(71) Applicant: Antony Trueman, Leesburg, VA (US)

(72) Inventor: Antony Trueman, Leesburg, VA (US)

(21) Appl. No.: 18/296,282

(22) Filed: Apr. 5, 2023

Related U.S. Application Data
(60) Provisional application No. 63/375,277, filed on Sep. 12, 2022.

(51) Int. Cl. G01N 17/02; G01N 27/04; G01R 15/12

(52) U.S. Cl. CPC G01N 17/02; G01N 27/045; G01R 15/12

(57) ABSTRACT

The present invention is an atmospheric resistance-based corrosion sensor that allows atmospheric corrosion rates to be measured, dynamically and frequently. The following are the components of the present invention. The resistance of a strip of 6 cm×0.5 cm and 50 μm thickness is approximately 40 mΩ at room temperature. This resistance is less than the any lead that would be required to measure it, and therefore a 4-point Kelvin measurement method was required. The present invention is broken down to four components: a sensor metallic strip [singular or multiple at ˜(50 μm-200 μm) manufactured from the metal of interest] conductively bonded to a circuit board with two conducting pads that link the circuits together, a first circuit that passes a known calibrated current, and a second circuit that passes no current.

### FIELD OF THE INVENTION

The present invention relates generally to a resistance-based sensor system for measuring atmospheric corrosion. More specifically, the present invention relates to atmospheric resistance-based corrosion sensor that allows atmospheric corrosion rates to be measured, dynamically and frequently.

### BACKGROUND OF THE INVENTION

Corrosion has been estimated to cost upwards of 8% of GDP per annum and can make structures unsafe for use. An understanding of the likelihood and rates of corrosion could significantly aid in reducing these risks. A significant proportion of corrosion occurs in the atmospheric environment where the likelihoods and rates can differ by several orders of magnitude. For example, coastal locations have much greater corrosion rates than arid rural locations. The mitigation of corrosion will be more effective if a reliable method to measure these rates was easily available.

The present invention aims to solve these problems. The present invention is an resistance-based sensor system that allows atmospheric corrosion rates to be measured, dynamically and frequently. This sensor replaces the current methods of exposing and analyzing corrosion coupons, a practice that requires cleaning in aggressive and toxic chemicals, is time consuming, requires a laboratory, and qualified labor to undertake. For these reasons, corrosion measurements are not widely used, and simple gross approximations are routinely employed. The sensor described here, can collect the same data, frequently and autonomously, making the measurements, more accurate, more accessible, less hazardous, and less costly. The following are the components of the present invention. The resistance of a strip of 6 cm×0.5 cm and 50 μm thickness is approximately 40 mΩ at room temperature. This resistance is less than the any lead that would be required to measure it, and therefore a 4-point Kelvin measurement method was required. This method is commonly available on high end multimeters and on some data loggers. It works by having two circuits the first passes a known calibrated current through the sensor metallic strip, the second is the sensing circuit that passes no current but measures the voltage. As the only part of the sensing circuit that passes current is the sensing strip, then this is isolated from the sensing leads and the strips resistance can be measured accurately. When manufactured on a circuit board two conducting pads are used to link the circuits together.

### BRIEF DESCRIPTION OF THE DRAWINGS

FIG. 1 is a block diagram of a system of the present invention.

FIG. 2 is a front view of the present invention.

FIG. 3 is a rear view of the present invention.

FIG. 4 is a flow diagram of the method of the present invention.

FIG. 5 is a flow diagram of a subprocess of the present invention.

FIG. 6 is a flow diagram of a subprocess of the present invention.

FIG. 7 is a flow diagram of a subprocess of the present invention.

FIG. 8 is a diagram of a 4-point resistance circuit.

FIG. 9 is a chart displaying changes in resistance of sensing strips with daily temperature changes.

FIG. 10 is a chart comparing the atmospheric temperature to the sensor strip temperature.

FIG. 11 is a chart comparing the sensor corrosion sectional loss and that measured using corrosion coupons.

### DETAIL DESCRIPTIONS OF THE INVENTION

All illustrations of the drawings are for the purpose of describing selected versions of the present invention and are not intended to limit the scope of the present invention.

This summary is provided to introduce a selection of concepts in a simplified form, that are further described below in the Detailed Description. This summary is not intended to identify key features or essential features of the claimed subject matter. Nor is this summary intended to be used to limit the claimed subject matter's scope.

As a preliminary matter, it will readily be understood by one having ordinary skill in the relevant art that the present disclosure has broad utility and application. As should be understood, any embodiment may incorporate only one or a plurality of the above-disclosed aspects of the disclosure and may further incorporate only one or a plurality of the above-disclosed features. Furthermore, any embodiment discussed and identified as being “preferred” is considered to be part of a best mode contemplated for carrying out the embodiments of the present disclosure. Other embodiments also may be discussed for additional illustrative purposes in providing a full and enabling disclosure. Moreover, many embodiments, such as adaptations, variations, modifications, and equivalent arrangements, will be implicitly disclosed by the embodiments described herein and fall within the scope of the present disclosure.

This invention details the design of a resistance-based sensor system that measures the corrosion rate of metals in atmospheric and other environments. When deployed next to a metallic structure it can infer a corrosion rate of that structure if like metals are selected. If the structure is painted, then the sensors can also be painted with the same coatings as the structure. This paint coating can also be damaged to mimic coatings damage experienced on the structure. The sensor could revolutionize the determination of corrosion rates of structures by making the measurement of corrosion significantly simpler than currently available methods. Raw sensor measurements can be easily used to calculated dynamic corrosion rates on the fly using simple calculations to determine the loss of metal by the change in the strips resistance. The sensor can be deployed with off-the shelf data logging systems or measured manually with a multimeter and thermocouple temperature meter.

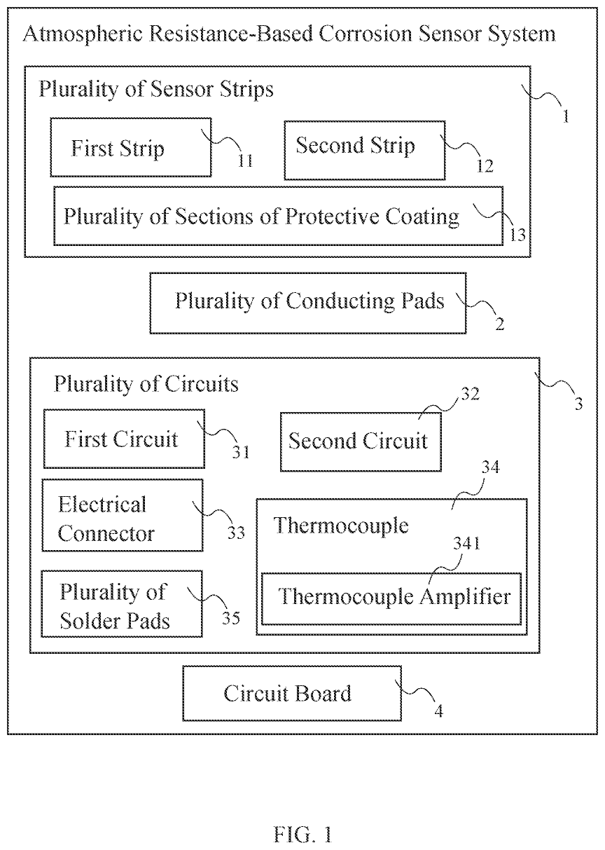

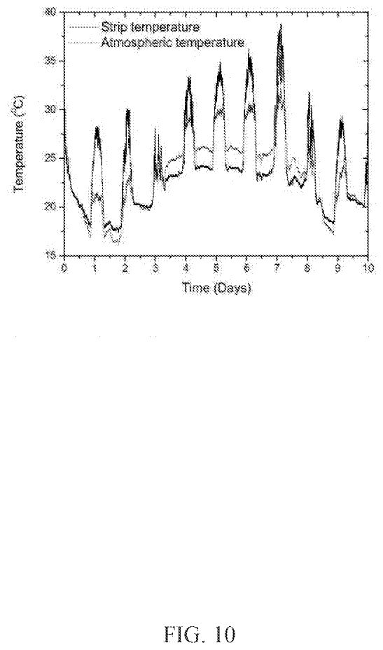

In reference to FIG. 1-11, the present invention is a resistance-based sensor system for measuring atmospheric corrosion that comprises a plurality of sensor strips 1, a plurality of conducting pads 2, a plurality of circuits 3, and a circuit board 4. The present invention further comprises a data logger or a multimeter. The plurality of sensor strips 1 comprises a first strips 11, a second strips 12, and a plurality of sections of protective coating 13. The plurality of circuits 3 comprises a first circuit 31, a second circuit 32, an electrical connector 33, a thermocouple 34, and a plurality of solder pads 35. The plurality of sensor strips 1 is positioned on the front of the circuit board 4. As a result, the plurality of sensor strips 1 can be easily exposed to the atmosphere to experience corrosion. The plurality of sensor strips 1 is positioned offset from each other. Consequently, each of the plurality of sensor strips 1 do not directly contact each other. The plurality of sensor strips 1 is a metallic material for which the atmospheric corrosion wants to be measured. Accordingly, the plurality of sensor strips 1 is designed with a variety of metals to match the material of a structure in the real-world environment that needs accurate corrosion measurements. The plurality of circuits 3 is mounted on the rear side of the circuit board 4. Thus, the plurality of circuits 3 is not directly exposed to the atmosphere and will not experience any corrosion. The plurality of conducting pads 2 is integrated into the circuit board 4. The plurality of conducting pads 2 electrically connects the plurality of sensor strips 1 to the plurality of circuits 3. So, the plurality of conducting pads 2 allows the plurality of circuits 3 to run currents and measure voltages in order to measure the corrosion of the plurality of sensor strips 1.

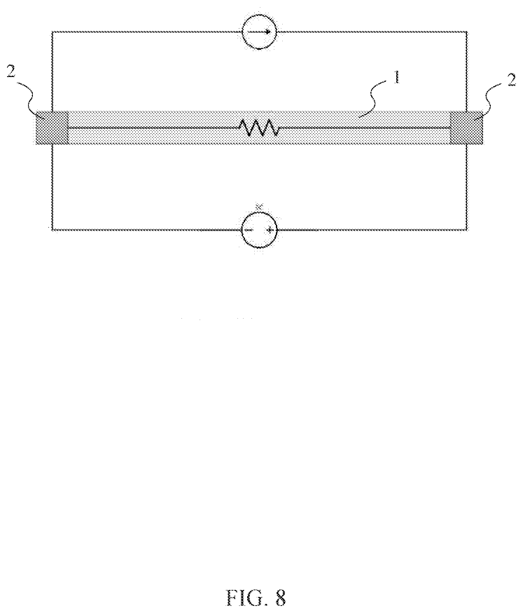

Further, the plurality of sensor strips 1 needs to be a certain size to obtain accurate measurements. The plurality of sensor strips 1 is at least 0.5 cm wide. Each of the plurality of sensor strips 1 has at least 3 cm² of surface area. The plurality of sensor strips 1 has a thickness of at least 50 μm. In an alternative embodiment the plurality of sensor strips 1 is designed with a smaller thickness when the expected atmospheric corrosion rates are expected to be low. The exposed surface area of the sensing strip needs to be large enough to account for the range of droplet sizes during wetness events of different magnitudes, the minimum size requirement has been estimated at 0.5 cm wide and have a minimum area of 3 cm². To ensure that the measurements are appropriate the sensing elements are made using thin shims of the specific metal/alloy, for example AISI 1010 steel, and that these shims have a thickness such that the corrosion occurs in a same manner as structural steel. It has been shown that thin metal films do not corrode as bulk specimens, the minimum thickness to be representative was found by experimentation to be a minimum thickness of 50 μm. The resistance of a strip of 6 cm×0.5 cm and 50 μm thickness is approximately 40 mil at room temperature. This resistance is less than the any lead that would be required to measure it, and therefore a 4-point Kelvin measurement method is required, as seen in FIG. 8. This method is commonly available on high end multimeters and on some data loggers. It works by having a plurality of circuits 3, the first circuit 31 passes a known calibrated current through one of the plurality of sensor strips 1, the second circuit 32 is the sensing circuit that passes no current but measures the voltage. As the only part of the sensing circuit that passes current is one of the plurality of sensor strips 1, then is isolated from the sensing leads and the plurality of sensor strips 1 resistance can be measured accurately. When manufactured on a circuit board 4 a plurality of conducting pads 2 is used to link the plurality of circuits 3 together. By using a large current on the first circuit 31, a measurable potential is generated that can be used to accurately calculate the resistance of the plurality of sensor strips 1. The resistivity of a metal has a significant temperature factor, for example the resistivity of steel is show in the equation:

Resistivity(ρ)=1.313×10⁻⁷+8.310×10⁻¹⁰×T(° C.)

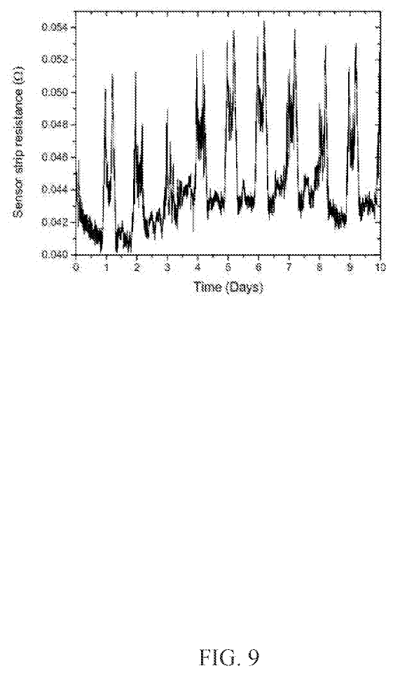

This resistivity equation indicates that for every 1° C. there is a 0.63% change in resistivity and thus the resistance. This is significant as the temperature of metals exposed to sunlight can change significantly, as seen in FIG. 9.

In reference to FIG. XX, the first strips 11 is positioned parallel to the second strips 12. The first strips 11 is not in direct contact with the second strips 12. As a result, the first strips 11 and the second strips 12 do not overlap and do not interfere with their individual respective measurements. The plurality of sections of protective coating 13 covers the terminal ends of the plurality of sensor strips 1. Consequently, the plurality of sections of protective coating 13 ensure that a section of the plurality of sensor strips 1 is not affected by corrosion.

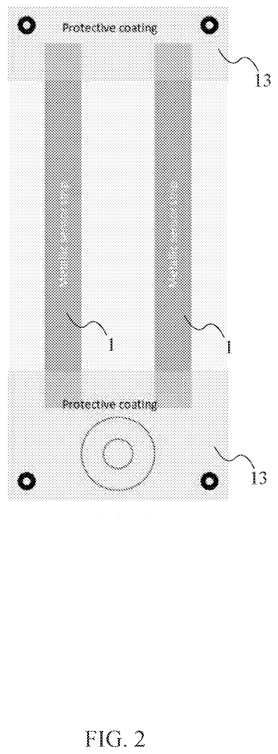

Further, the plurality of sections of protective coating 13 prevents the terminal ends of the plurality of sensor strips 1 from being exposed to the elements as seen in FIG. 2. The plurality of sections of protective coating 13 prevents the terminal ends of the plurality of sensor strips 1 from corroding. Accordingly, to not expose the plurality of conducting pads 2 and the plurality of solder pads 35 to the elements a portion of the plurality of sensor strips 1 must be covered with the plurality of sections of protective coating 13 that serves as a barrier layer. This proportion of the plurality of sensor strips 1 will not corrode and therefore must be accounted for in the calculation of corrosion loss of the exposed portion.

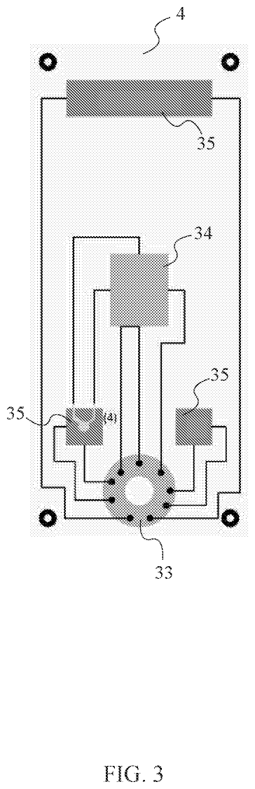

In reference to FIG. 3, the first circuit 31 is positioned offset the second circuit 32. Thus, the first circuit 31 does not interfere or interact with the second circuit 32. The electrical connector 33 electrically connects the first circuit 31, the second circuit 32, the thermocouple 34, and the plurality of solder pads 35 with electrical traces. So, the electrical connector 33 allows the first circuit 31, the second circuit 32, the thermocouple 34, and the plurality of solder pads 35 to create closed loop circuits. The electrical connector 33 is positioned at the bottom of the circuit board 4. The electrical connector 33 is positioned below the plurality of sections of protective coating 13. As a result, the electrical connector 33 is protected from the atmospheric elements and will not experience corrosion.

Further, the plurality of solder pads 35 is positioned below the terminal ends of the plurality of sensor strips 1. Consequently, the plurality of solder pads 35 link the plurality of circuits 3 together. The plurality of solder pads 35 is in contact with the plurality of sensor strips 1. The thermocouple 34 is positioned in between the plurality of sensor strips 1 as seen in FIG. 3. Accordingly, the thermocouple 34 can measure the temperature of the plurality of sensor strips 1. The thermocouple 34 is connected directly to each of the sensor strips.

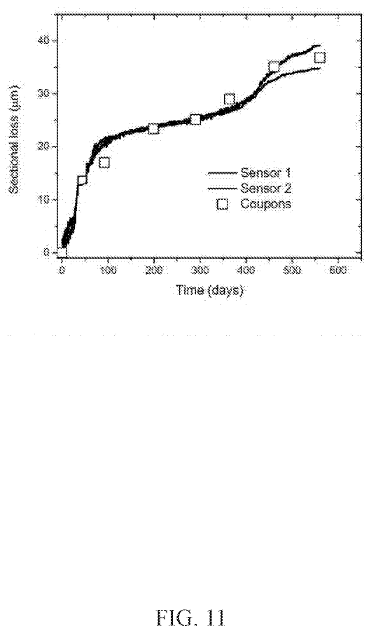

Furthermore, the thermocouple 34 comprises a thermocouple amplifier 341 as seen in FIG. 1. The thermocouple amplifier 341 levels the thermocouple 34 connection with the plurality of sensor strips 1 temperature with a cold junction temperature. To accurately measure the resistance and therefore the corrosion rate, the resistance measurements need to be corrected for resistivity changes. This was achieved by setting a standard temperature and adjusting the resistance of the strips to this temperature, using the measured metal surface temperature. External thermocouples have been attempted to be used, and mounted on the sensor racks, but the thermal mass was different for this system. The thermocouple 34 being directly to the plurality of sensor strips 1 allows for an accurate measurement. This in turn required thermocouple amplifier 341 to ensure the amplifiers cold junction temperature was the same as the thermocouple 34 connections to the plurality of sensor strips 1. The plurality of circuits 3 can accurately measure the resistance of the plurality of sensor strips 1, that is increased as corrosion occurs and therefore a corrosion rate can be determined. The resistance of the plurality of sensor strips 1 also changes with temperature, as resistivity has a temperature coefficient, in atmospheric conditions these changes are significant and give gross inaccuracies to the determined corrosion rates. This is overcome by using a responsive measurement of the temperature of the plurality of strips using the thermocouple 34 attached directly to the plurality of sensing strips and connected to a thermocouple amplifier 341 that is secured on the circuit board 4. The thermocouple amplifier 341 ensures that the thermocouple 34 connections to the plurality of sensor strips 1 are at the same temperature as the cold junction for the thermocouple amplifier 341. The plurality of sensor strips 1 is designed for atmospheric conditions but could also be used in immersed environments. It can be manufactured with most metals of interest but is more valuable to the measurement of general corrosion rates and is designed for ease of manufacture, and use, and can be easily integrated with a data logger or measured with a handheld multimeter. The plurality of sensor strips 1 will eliminate the need for laboratory to undertake the pre and post deployment analysis that is required for corrosion coupons and can give frequent measurements of corrosion loss as seen in FIG. 11, where the present invention is compared to the industry standard corrosion coupons.

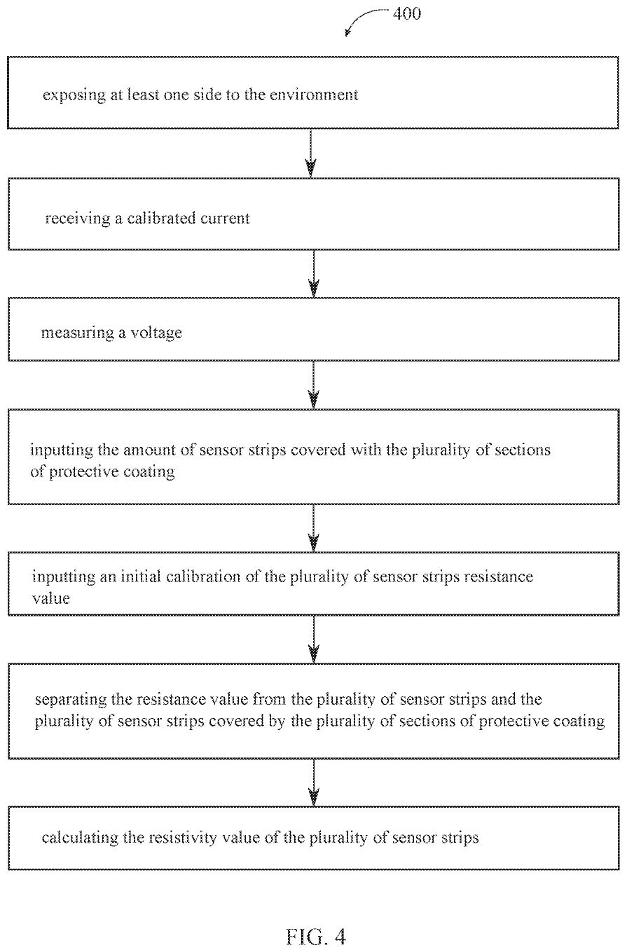

As can be seen in FIG. 4 through FIG. 7, the preferred embodiment of the present invention is a method for measuring atmospheric corrosion. To accomplish this, the method 400 of the present invention exposes at least one side to the environment. The system used to execute the method of the present invention receives a calibrated current. Then the system measures a voltage. Next, the method of the present invention inputs the amount of sensor strips covered with the plurality of sections of protective coating 13. Afterwards, the system inputs an initial calibration of the plurality of sensor strips 1 resistance value. To execute the method of the present invention the system of the present invention separates the resistance value from the plurality of sensor strips 1 and the plurality of sensor strips 1 covered by the plurality of sections of protective coating 13. Finally, the method calculates the resistivity value of the plurality of sensor strips 1. These calculations require an initial calibration of the plurality of sensing strips resistance at a static and known temperature. This resistance is then separated into resistance from the coated and exposed portions of the plurality of sensor strips 1, by accurately measuring the exposed area of the plurality of sensor strips 1, combined with the calibrated resistance. These resistance values are then normalized to a standard temperature of 0.0° C. using the resistivity equation above. The deployed measured resistance is then normalized to the same standard temperature and the resistance of the covered portion of the plurality of sensor strips 1 can be subtracted and the change of the resistance of the exposed portion of the plurality of sensor strips 1 can be calculated. A comparison of the initial and final normalized resistances of the exposed portion of the plurality of sensor strips 1 can be used using Ohms law to calculate the sectional loss.

Resistance(Ω)=Resistivity(ρ)×length/area(width×depth)

As normalized resistances have constant resistivity and the length and width are also constant then:

Sectional loss=Initial strip depth−final strip depth

Final strip depth=(Initial resistance×initial depth)/final resistance

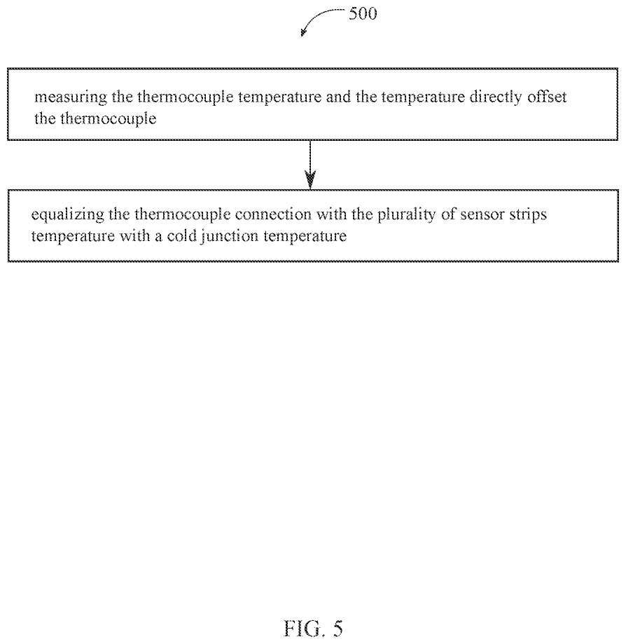

In reference to FIG. 5, a sub-process 500 of the method of the present invention enables the present invention to measure the temperature of the system. To that end, the sub-process measures the thermocouple 34 temperature and the temperature directly offset the thermocouple 34. The sub-process continues and equalizes the thermocouple 34 connection with the plurality of sensor strips 1 temperature with a cold junction temperature.

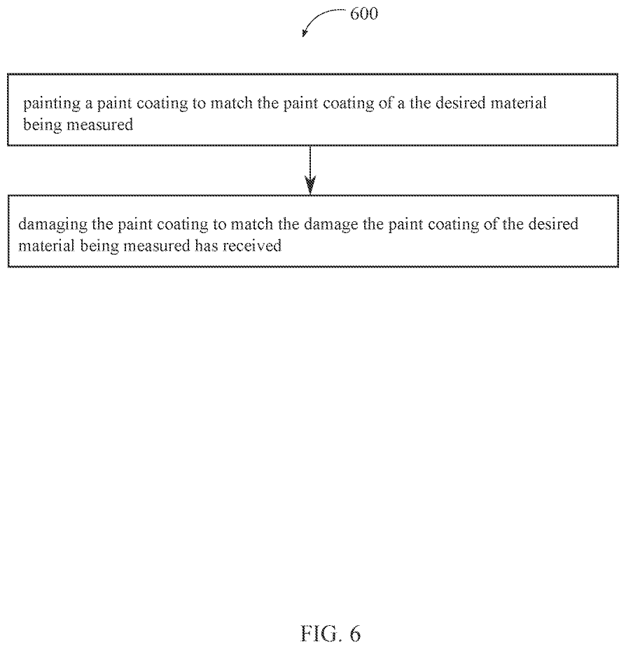

In reference to FIG. 6, a sub-process 600 of the method of the present invention enables the present invention to measure the corrosion of materials with paint coatings. To that end, the sub-process begins by painting a paint coating to match the paint coating of the desired material being measured. The sub-process continues by damaging the paint coating to match the damage the paint coating of the desired material being measured has received.

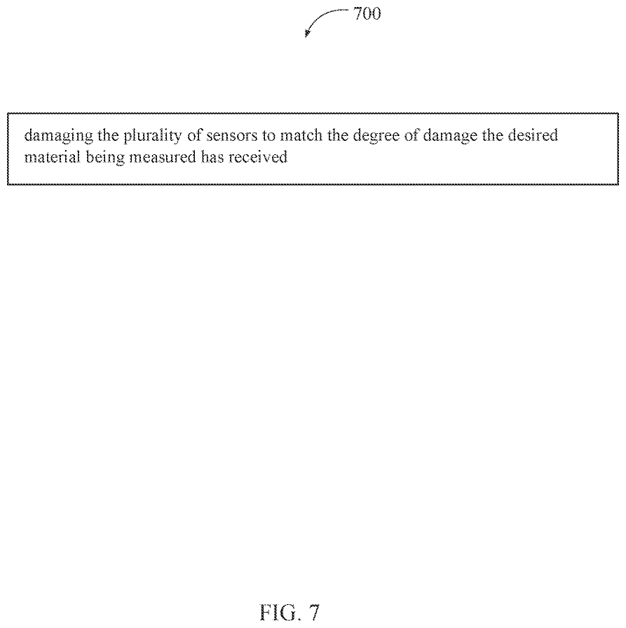

In reference to FIG. 7, a sub-process 700 of the method of the present invention enables the present invention to measure the corrosion of materials with damage. To that end, the sub-process damages the plurality of sensors to match the degree of damage the desired material being measured has received.

Although the invention has been explained in relation to its preferred embodiment, it is to be understood that many other possible modifications and variations can be made without departing from the spirit and scope of the invention.

It will be apparent to those skilled in the art that various modifications and variations can be made in the practice of the present invention without departing from the scope or spirit of the invention. Other embodiments of the invention will be apparent to those skilled in the art from considering of the specification and practice of the invention. It is intended that the specification and examples be considered as exemplary only, with a true scope and spirit of the invention being indicated by the following claims.

The present invention is an resistance-based sensor system that allows atmospheric corrosion rates to be measured, dynamically and frequently. The following are the components of the present invention. The resistance of a strip of 6 cm×0.5 cm and 50 μm thickness is approximately 40 mΩ at room temperature. This resistance is less than the any lead that would be required to measure it, and therefore a 4-point Kelvin measurement method was required. The present invention is broken down to four components: a sensor metallic strip [singular or multiple at˜(50 μm-200 μm) manufactured from the metal of interest] conductively bonded to a circuit board 4 two conducting pads that link the circuits together, a first circuit 31 that passes a known calibrated current, and a second circuit 32 that passes no current.

Although the invention has been explained in relation to its preferred embodiment, it is to be understood that many other possible modifications and variations can be made without departing from the spirit and scope of the invention as hereinafter claimed.

What is claimed is:

1. A resistance-based sensor system for measuring atmospheric corrosion comprising:
a plurality of sensor strips;
a plurality of conducting pads;
a plurality of circuits;
a circuit board;
a data logger or a multimeter;
the plurality of sensor strips comprising a first strip, a second strip, and a plurality of sections of protective coating;
the plurality of circuits comprising a first circuit, a second circuit, an electrical connector, a thermocouple, and a plurality of solder pads;
the plurality of sensor strips being positioned on the front of the circuit board;
the plurality of sensor strips being positioned offset from each other;
the plurality of sensor strips being a metallic material for which the atmospheric corrosion wants to be measured;
the plurality of circuits being mounted on the rear side of the circuit board;
the plurality of conducting pads being integrated into the circuit board; and
the plurality of conducting pads electrically connecting the plurality of sensor strips to the plurality of circuits.

2. The resistance-based sensor system for measuring atmospheric corrosion as claimed in claim 1 comprising:
the plurality of sensor strips being at least 0.5 cm wide;
each of the plurality of sensor strips having at least 3 cm² of surface area; and
the plurality of sensor strips having a thickness of at least 50 μm.

3. The resistance-based sensor system for measuring atmospheric corrosion as claimed in claim 1 comprising:
the first strip being positioned parallel to the second strip;
the first strip not being in direct contact with the second strip; and
the plurality of sections of protective coating being configured to prevent the terminal ends of the plurality of sensor strips from corroding.

4. The resistance-based sensor system for measuring atmospheric corrosion as claimed in claim 3 comprising:
the plurality of sections of protective coating being configured to prevent the terminal ends of the plurality of sensor strips from being exposed to the elements; and
the plurality of sections of protective coating being configured to prevent the terminal ends of the plurality of sensor strips from corroding.

5. The resistance-based sensor system for measuring atmospheric corrosion as claimed in claim 1 comprising:
the first circuit being positioned offset the second circuit;
the electrical connector electrically connecting the first circuit, the second circuit, the thermocouple, and the plurality of solder pads with electrical traces;
the electrical connector being positioned at the bottom of the circuit board; and
the electrical connector being positioned below the plurality of sections of protective coating.

6. The resistance-based sensor system for measuring atmospheric corrosion as claimed in claim 5 comprising:
the plurality of solder pads being positioned below the terminal ends of the plurality of sensor strips; and
the plurality of solder pads being in contact with the plurality of sensor strips.

7. The resistance-based sensor system for measuring atmospheric corrosion as claimed in claim 5 comprising:
the thermocouple being positioned in between the plurality of sensor strips; and
the thermocouple being connected directly to each of the sensor strips.

8. The resistance-based sensor system for measuring atmospheric corrosion as claimed in claim 6, wherein the thermocouple comprises a thermocouple amplifier.

9. The resistance-based sensor system for measuring atmospheric corrosion as claimed in claim 8, wherein the thermocouple amplifier is configured to level the thermocouple connection with the plurality of sensor strips temperature with a cold junction temperature.

10. A method for measuring atmospheric corrosion comprising:
providing a resistance-based sensor system, the system comprising:
a plurality of sensor strips;
a plurality of conducting pads;
a plurality of circuits;
a circuit board;
a data logger;
a multimeter;
the plurality of sensor strips comprising a first strip, a second strip, and a plurality of sections of protective coating;
the plurality of circuits comprising a first circuit, a second circuit, an electrical connector, a thermocouple, and a plurality of solder pads;
the thermocouple comprising a thermocouple amplifier;
exposing, using the plurality of sensor strips, at least one side to the environment;
receiving, using the first circuit, a calibrated current;
measuring, using the second circuit, a voltage;
inputting, using the data logger, the amount of sensor strips covered with the plurality of sections of protective coating;
inputting, using the data logger, an initial calibration of the plurality of sensor strips resistance value;
separating, using the data logger, the resistance value from the plurality of sensor strips and the plurality of sensor strips covered by the plurality of sections of protective coating; and
calculating the resistivity value of the plurality of sensor strips.

11. The method for measuring atmospheric corrosion as claimed in claim 10 comprising:
measuring, using the thermocouple amplifier, the thermocouple temperature and the temperature directly offset the thermocouple; and
equalizing, using the thermocouple amplifier, the thermocouple connection with the plurality of sensor strips temperature with a cold junction temperature.

12. The method for measuring atmospheric corrosion as claimed in claim 10 comprising:
painting, using the plurality of sensors, a paint coating to match the paint coating of a desired material being measured; and
damaging, using the plurality of sensors, the paint coating to match the damage the paint coating of the desired material being measured has received.

13. The method for measuring atmospheric corrosion as claimed in claim 10 comprising:
damaging, using the plurality of sensors, the plurality of sensors to match the degree of damage the desired material being measured has received.

14. A resistance-based sensor system for measuring atmospheric corrosion comprising:
a plurality of sensor strips;
a plurality of conducting pads;
a plurality of circuits;
a circuit board;
a data logger or a multimeter;
the plurality of sensor strips comprising a first strip, a second strip, and a plurality of sections of protective coating;
the plurality of circuits comprising a first circuit, a second circuit, an electrical connector, a thermocouple, and a plurality of solder pads;
the plurality of sensor strips being positioned on the front of the circuit board;
the plurality of sensor strips being positioned offset from each other;
the plurality of sensor strips being a metallic material for which the atmospheric corrosion wants to be measured;
the plurality of circuits being mounted on the rear side of the circuit board;
the plurality of conducting pads being integrated into the circuit board; and
the plurality of conducting pads electrically connecting the plurality of sensor strips to the plurality of circuits.

15. The resistance-based sensor system for measuring atmospheric corrosion as claimed in claim 14 comprising:
the plurality of sensor strips being at least 0.5 cm wide;
each of the plurality of sensor strips having at least 3 cm² of surface area; and
the plurality of sensor strips having a thickness of at least 50 μm.

16. The resistance-based sensor system for measuring atmospheric corrosion as claimed in claim 14 comprising:
the first strip being positioned parallel to the second strip;
the first strip not being in direct contact with the second strip; and
the plurality of sections of protective coating being configured to prevent the terminal ends of the plurality of sensor strips from corroding.

17. The resistance-based sensor system for measuring atmospheric corrosion as claimed in claim 16 comprising:
the plurality of sections of protective coating being configured to prevent the terminal ends of the plurality of sensor strips from being exposed to the elements; and
the plurality of sections of protective coating being configured to prevent the terminal ends of the plurality of sensor strips from corroding.

18. The resistance-based sensor system for measuring atmospheric corrosion as claimed in claim 14 comprising:
the first circuit being positioned offset the second circuit;
the electrical connector electrically connecting the first circuit, the second circuit, the thermocouple, and the plurality of solder pads with electrical traces;
the electrical connector being positioned at the bottom of the circuit board; and
the electrical connector being positioned below the plurality of sections of protective coating.

19. The resistance-based sensor system for measuring atmospheric corrosion as claimed in claim 18 comprising:
the plurality of solder pads being positioned below the terminal ends of the plurality of sensor strips; and
the plurality of solder pads being in contact with the plurality of sensor strips.

20. The resistance-based sensor system for measuring atmospheric corrosion as claimed in claim 18 comprising:
the thermocouple being positioned in between the plurality of sensor strips;
the thermocouple being connected directly to each of the sensor strips;
the thermocouple comprising a thermocouple amplifier; and
the thermocouple amplifier being configure to level the thermocouple connection with the plurality of sensor strips temperature with a cold junction temperature.
